(19) United States
(12) Patent Application Publication
(10) Pub. No.: US 2026/0302072 A1
(43) Pub. Date: Oct. 1, 2026

(54) MULTILAYER ELECTRONIC COMPONENT AND BOARD HAVING THE SAME MOUNTED THEREON

(71) Applicant: SAMSUNG ELECTRO-MECHANICS CO., LTD., Suwon-si (KR)

(72) Inventors: Soo Hwan SON, Suwon-si (KR); Se Hun PARK, Suwon-si (KR); Yeong Lim KWON, Suwon-si (KR)

(73) Assignee: SAMSUNG ELECTRO-MECHANICS CO., LTD., Suwon-si (KR)

(21) Appl. No.: 19/530,531

(22) Filed: Feb. 5, 2026

(30) Foreign Application Priority Data
Mar. 26, 2025 (KR) 10-2025-0038504

(51) Int. Cl. H01G 4/30; H01G 4/224; H01G 4/232; H05K 1/181

(52) U.S. Cl. CPC H01G 4/30; H01G 4/224; H01G 4/2325; H05K 1/181; H05K 2201/10015

(57) ABSTRACT

A multilayer electronic component may include: a body including a dielectric layer and internal electrodes; an external electrode disposed on the body; and a coating layer disposed on the first and second surfaces, and when an average thickness of a coating layer disposed on the first surface, among the coating layer, is referred to as TCL1 and an average thickness of a remaining coating layer excluding the coating layer disposed on the first surface is referred to as TCL2, TCL2<TCL1 and 2 μm≤TCL2≤6 μm may be satisfied.

### CROSS-REFERENCE TO RELATED APPLICATION(S)

This application claims benefit of priority to Korean Patent Application No. 10-2025-0038504 filed on Mar. 26, 2025, in the Korean Intellectual Property Office, the disclosure of which is incorporated herein by reference in its entirety.

### TECHNICAL FIELD

The present disclosure relates to a multilayer electronic component and a board having the same mounted thereon.

Multilayer ceramic capacitors (MLCC), a type of multilayer electronic component, are chip-shaped capacitors mounted on the printed circuit boards of various electronic devices, including Liquid Crystal Displays (LCD) and Plasma Display Panels (PDP), computers, smartphones, and mobile phones to charge or discharge electricity therein or therefrom.

Such multilayer ceramic capacitors may be used as a component of various electronic devices due to a small size thereof, high capacity, and ease of mounting. As electronic devices, such as computers and mobile devices, become smaller and more powerful, demand for miniaturized and higher-capacity multilayer ceramic capacitors has increased.

Multilayer ceramic capacitors, a type of multilayer electronic component, include a dielectric material, and since the dielectric material may exhibit piezoelectric properties, the dielectric material may be deformed in synchronization with the applied voltage.

Applied AC voltage may thus generate piezoelectric vibrations in the MLCC, and such vibrations may be transmitted to the board through the MLCC and a solder, causing the board to vibrate. When the noise from the board vibration is within the audible frequency range, this is experienced as noise, but this sound is referred to as acoustic noise.

If the device′ operating environment is quiet, such acoustic noise may be perceived as an abnormal sound by a user, potentially indicating a malfunction. Furthermore, in devices having audio circuits, acoustic noise may be superimposed on an audio output, which may degrade device′ quality. Furthermore, separate from the acoustic noise perceived by the human ear, noise generated by board vibrations at frequencies exceeding 20 kHz may cause malfunctions in various sensors used in IT, industrial, and electrical fields.

In addition, since small multilayer ceramic capacitors are densely mounted at narrow intervals on the substrate, mountability is also evaluated as an important factor, and it is important to dispose the multilayer ceramic capacitors in an intended mounting position after performing a reflow process after applying solder, but when a mounting defect occurs, this may have a negative effect on the entire product.

### SUMMARY

An aspect of the present disclosure is to provide a multilayer electronic component having improved acoustic noise and a board having the same mounted thereon.

An aspect of the present disclosure is to provide a multilayer electronic component having improved mountability and a board having the same mounted thereon.

However, the aspects of the present disclosure are not limited to the above-described contents, and may be more easily understood in the process of describing specific embodiments of the present disclosure.

A multilayer electronic component according to an example embodiment of the present disclosure may include: a body including a dielectric layer and internal electrodes alternately disposed with the dielectric layer in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction; an external electrode disposed on the body; and a coating layer disposed on the first and second surfaces, the coating layer including a first portion disposed on the first surface, and a second portion that is free of the first portion, and when an average thickness of the first portion is referred to as TCL1 and an average thickness of the second portion is referred to as TCL2, TCL2<TCL1 and 2 μm=TCL2≤6 μm may be satisfied.

A board having a multilayer electronic component mounted thereon according to another example embodiment of the present disclosure may include: a substrate; an electrode pad disposed on the substrate; a multilayer electronic component including a body having a dielectric layer and internal electrodes alternately disposed with the dielectric layer in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction, an external electrode disposed on the body, and a coating layer disposed on the first and second surfaces, the coating layer including a first portion disposed on the first surface, and a second portion that is free of the first portion; and a solder connecting the external electrode and the electrode pads, when an average thickness of the first portion is referred to as TCL1 and an average thickness of the second portion is referred to as TCL2, TCL2<TCL1 and 2 μm≤TCL2≤6 μm may be satisfied.

One of the various effects of the present disclosure is to improve acoustic noise of a multilayer electronic component.

One of the various effects of the present disclosure is to improve the mountability of a multilayer electronic component.

However, the various and beneficial advantages and effects of the present disclosure are not limited to the above-described contents, and may be more easily understood in the process of describing specific embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates a perspective view of a multilayer electronic component according to an example embodiment of the present disclosure;

FIG. 2 schematically illustrates a cross-sectional view taken along line I-I′ of FIG. 1;

FIG. 3 schematically illustrates a cross-sectional view taken along line II-II′ of FIG. 1;

FIG. 4 schematically illustrates a perspective view of a mounting board and a multilayer electronic component according to another example embodiment of the present disclosure; and

FIG. 5 schematically illustrates a cross-sectional view taken along line III-III′ of FIG. 4.

### DETAILED DESCRIPTION

Hereinafter, example embodiments of the present disclosure will be described with reference to specific example embodiments and the attached drawings. The example embodiments of the present disclosure may, however, be exemplified in many different forms and should not be construed as being limited to the specific example embodiments set forth herein. The example embodiments disclosed herein are provided for those skilled in the art to better explain the present disclosure. In the drawings, the shapes and dimensions of elements may be exaggerated for clarity, and the same reference numerals will be used throughout to designate the same or like elements.

Furthermore, in order to clearly describe the present disclosure in the drawings, contents unrelated to the description are omitted, and since sizes and thicknesses of each component illustrated in the drawings are arbitrarily illustrated for convenience of description, the present disclosure is not limited thereto. Furthermore, components with the same function within the same range of ideas are described using the same reference numerals. Throughout the specification, when a certain portion “includes” or “comprises” a certain component, this indicates that other components are not excluded and may be further included unless otherwise noted.

In the drawing, a Z-direction may be defined as a thickness direction or a first direction, an X-direction may be a length direction or a second direction, and a Y-direction may be a width direction or a third direction. Additionally, a stacking direction may be a thickness direction or a width direction.

### Multilayer Electronic Component

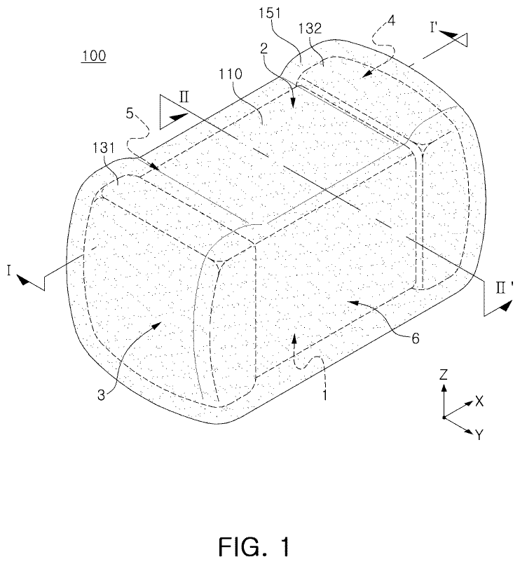

FIG. 1 schematically illustrates a perspective view of a multilayer electronic component according to an example embodiment of the present disclosure.

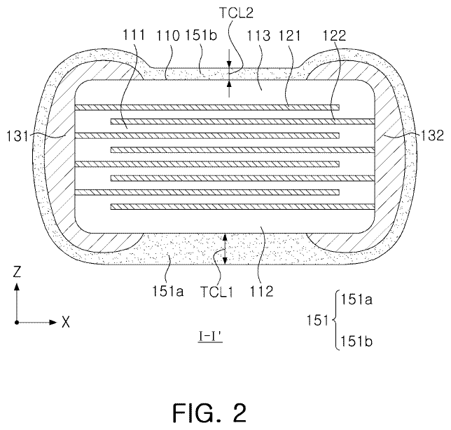

FIG. 2 schematically illustrates a cross-sectional view taken along line I-I′ of FIG. 1.

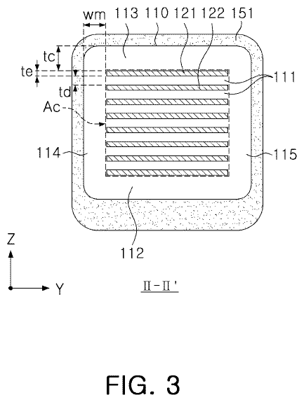

FIG. 3 schematically illustrates a cross-sectional view taken along line II-II′ of FIG. 1.

Hereinafter, a multilayer electronic component according to an example embodiment of the present disclosure will be described in detail with reference to FIGS. 1 to 3. While a multilayer ceramic capacitor will be described as an example of a multilayer electronic component, the present disclosure may also be applied to various electronic products utilizing dielectric compositions, such as inductors, piezoelectric elements, varistors, or thermistors.

A multilayer electronic component 100 according to an example embodiment of the present disclosure includes: a body 110 including a dielectric layer 111 and internal electrodes 121 and 122 alternately disposed in a thickness direction with the dielectric layer 111, and first and second surfaces 1 and 2 opposing each other in the thickness direction, third and fourth surfaces 3 and 4 connected to the first and second surfaces 1 and 2 and opposing each other in a length direction, and fifth and sixth surfaces 5 and 6 connected to the first to fourth surfaces 1, 2, 3 and 4 and opposing each other in a width direction; external electrodes 131 and 132 disposed on the body 110; and a coating layer 151 disposed on the first and second surfaces 1 and 2, and when an average thickness of a coating layer 151a (e.g., first portion of the coating layer) disposed on the first surface 1 among the coating layers 151 is referred to as TCL1, and an average thickness of the remaining coating layers 151b (e.g., the second portion of the coating layer) excluding the coating layer 151a disposed on the first surface 1 is referred to as TCL2, TCL2<TCL1 and 2 μm≤TCL2≤6 μm may be satisfied.

The body 110 may have a dielectric layer 111 and internal electrodes 121 and 122 alternately stacked.

More specifically, the body 110 may include a capacitance formation portion Ac forming a capacitance, by including a first internal electrode 121 and a second internal electrode 122 disposed inside the body 110 and alternately disposed to face each other with the dielectric layer 111 interposed therebetween.

Although there is no particular limitation on the specific shape of the body 110, as illustrated, the body 110 may be formed into a hexahedron or a similar shape. Due to the shrinkage of the ceramic particles included in the body 110 during the firing process, the body 110 may not have a perfectly straight hexahedron shape, but may have a substantially hexahedron shape.

The body 110 may have first and second surfaces 1 and 2 opposing each other in the thickness direction, third and fourth surfaces 3 and 4 connected to the first and second surfaces 1 and 2 and opposing each other in a length direction, and fifth and sixth surfaces 5 and 6 connected to the first to fourth surfaces 1, 2, 3 and 4 and opposing each other in the width direction.

A plurality of dielectric layers 111 forming the body 110 are in a sintered state, and boundaries between adjacent dielectric layers 111 may be integrated to be difficult to identify without using a scanning electron microscope (SEM).

A raw material forming the dielectric layer 111 is not limited as long as this may achieve sufficient electrostatic capacity. Typically, a perovskite (ABO₃)-based material may be used. Barium titanate-based materials, lead composite perovskite-based materials, or strontium titanate-based materials may be used. The barium titanate-based material may include BaTiO₃-based ceramic particles. Examples of the ceramic particles include BaTiO₃, and (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), or Ba(Ti_{1-y}Zr_{y})O₃ (0<y<1) which is formed by partially employing calcium (Ca) and zirconium (Zr) in BaTiO₃.

Furthermore, in the raw material forming the dielectric layer 111, particles such as barium titanate (BaTiO₃) may be added to which various ceramic additives, organic solvents, binders, dispersants, and the like, may be added, depending on the purpose of the present disclosure.

Meanwhile, in order to distinguish the dielectric layer included in the capacitance formation portion Ac from dielectric layers included in the cover portions 112 and 113 and side margin portions 114 and 115 described below, the dielectric layer included in the capacitance formation portion Ac may be defined as a first dielectric layer, the dielectric layer included in the cover portions 112 and 113 may be defined as a second dielectric layer, and the dielectric layer included in the side margin portions 114 and 115 may be defined as a third dielectric layer.

The first to third dielectric layers may be formed using a dielectric material such as barium titanate (BaTiO₃), and thus may include a dielectric microstructure after sintering. A dielectric microstructure may include a plurality of grains, grain boundaries between adjacent grains, and triple points disposed at points where three or more grain boundaries meet, and each of the grains, grain boundaries, and triple points may be provided in plural.

A thickness td of the dielectric layer 111 is not particularly limited.

However, in order to more easily achieve miniaturization and high capacity of the multilayer electronic component, an upper limit of the thickness td of the dielectric layer 111 may be 1.5 μm or less, 1.2 μm or less, 1.0 μm or less, 0.8 μm or less, or 0.6 μm or less, and in order to achieve ultra-miniaturization, the upper limit thereof may be 0.5 μm or less, or 0.4 μm or less, and a lower limit thereof may be 0.1 μm or more, 0.2 μm or more, or 0.3 μm or more.

Here, the thickness td of the dielectric layer 111 may refer to a thickness td of the dielectric layer 111 disposed between the first and second internal electrodes 121 and 122.

In this case, the thickness td of the dielectric layer 111 may be a concept including the thickness td of any one of the plurality of dielectric layers 111, or may be a concept including the thickness td of each of all the dielectric layers 111.

In addition, the thickness td of the dielectric layer 111 may refer to an average thickness td of one dielectric layer 111, may refer to an average thickness td of each of the plurality of dielectric layers 111, or may refer to an average thickness td of the plurality of dielectric layers 111.

The average thickness td of the dielectric layer 111 may be measured by scanning an image of a cross-section of the length and thickness directions of the body 110 using a scanning electron microscope (SEM) at 10,000× magnification. More specifically, the average thickness td of one dielectric layer 111 may refer to an average value calculated by measuring the thickness at five points spaced apart from each other by equal intervals in the longitudinal direction of one dielectric layer 111 in a scanned image. The five equally spaced points may be designated in the capacitance formation portion Ac.

Additionally, when the average value is measured by extending an average value measurement up to three dielectric layers 111, the average thickness td of the plurality of dielectric layers 111 may be further generalized.

The internal electrodes 121 and 122 may be alternately stacked with the dielectric layer 111.

The internal electrodes 121 and 122 may include a first internal electrode 121 and a second internal electrode 122, and the first and second internal electrodes 121 and 122 are alternately disposed to face each other with the dielectric layer 111 forming the body 110 interposed therebetween, and may be exposed through the third and fourth surfaces 3 and 4 of the body 110, respectively.

More specifically, the first internal electrode 121 may be spaced apart from the fourth surface 4 and may be exposed through the third surface 3, and the second internal electrode 122 may be spaced apart from the third surface 3 and exposed through the fourth surface 4. The first external electrode 131 may be disposed on the third surface 3 of the body 110 and may be connected to the first internal electrode 121, and the second external electrode 132 may be disposed on the fourth surface 4 of the body 110 and may be connected to the second internal electrode 122.

That is, the first internal electrode 121 may be connected to the first external electrode 131 without being connected to the second external electrode 132, and the second internal electrode 122 may be connected to the second external electrode 132 without being connected to the first external electrode 131. In this case, the first and second internal electrodes 121 and 122 may be electrically isolated from each other by a dielectric layer 111 disposed therebetween.

Meanwhile, the body 110 may be formed by alternately stacking a first ceramic green sheet on which a first internal electrode paste which is to be the first internal electrode 121 is printed and the first ceramic green sheet printed on which a second internal electrode paste which is to be the second internal electrode 122 is printed, and then sintering the first ceramic green sheet. A printing method for the conductive paste for the internal electrodes may be screen-printing or gravure printing, or the like, and the present disclosure is not limited thereto.

A material forming the internal electrodes 121 and 122 is not particularly limited, and any material with excellent electrical conductivity may be used. For example, the internal electrodes 121 and 122 may include one or more of nickel (Ni), copper (Cu), palladium (Pd), silver (Ag), gold (Au), platinum (Pt), tin (Sn), tungsten (W), titanium (Ti), and alloys thereof.

Meanwhile, a thickness the of the internal electrodes 121 and 122 need not be specifically limited, and hereinafter, the description of the thickness the of the internal electrodes 121 and 122 may refer to the thickness the of each of the first internal electrode 121 and the second internal electrode 122.

In order to achieve miniaturization and high capacity of the multilayer electronic component 100, the thickness the of the internal electrodes 121 and 122 may be 1.0 μm or less, 0.8 μm or less, or 0.6 μm or less, and in order to achieve ultra-miniaturization, the thickness the may be 0.5 μm or less, or 0.4 μm or less.

In this case, the thickness the of the internal electrodes 121 and 122 may be a concept including the thickness the of at least one of the plurality of internal electrodes 121 and 122, or may be a concept including the thickness the of all internal electrodes 121 and 122.

In this case, the thickness the of the internal electrodes 121 and 122 may be a concept including the thickness the of at least one of the plurality of internal electrodes 121 and 122, or may be a concept including the thickness the of each of the plurality of internal electrodes 121 and 122.

Additionally, the thickness the of the internal electrodes 121 and 122 may refer to the average thickness the of one internal electrode 121 or 122, or may refer to the average thickness the of each of a plurality of internal electrodes 121 and 122, or may refer to the average thickness the of a plurality of internal electrodes 121 and 122.

The average thickness the of the internal electrodes 121 and 122 may be measured by scanning an image of a cross-section in length and thickness directions of the body 110 using a scanning electron microscope (SEM) at 10,000× magnification. More specifically, the average thickness the of one internal electrode 121 or 122 may be an average value calculated by measuring a thickness of one internal electrode at five points spaced apart from each other by equal intervals in the length direction in the scanned image. The five equally spaced points may be designated in the capacitance formation portion Ac. Furthermore, when the average value is measured by extending an average value measurement up to three internal electrodes 121 and 122, an average thickness the of the plurality of internal electrodes 121 and 122 may be further generalized.

Meanwhile, the body 110 may include cover portions 112 and 113 disposed on both end surfaces of the capacitance formation portion Ac in the thickness direction.

Specifically, the body 110 may include a first cover portion 112 disposed on one surface of the capacitance formation portion Ac in the thickness direction and a second cover portion 113 disposed on the other surface of the capacitance formation portion Ac in the thickness direction. More specifically, the body 110 may include a first cover portion 112 disposed in a lower portion of the capacitance formation portion Ac in the thickness direction and a second cover portion 113 disposed in a lower portion of the capacitance formation portion Ac in the thickness direction.

The first cover portion 112 and the second cover portion 113 may be formed by disposing or stacking a single second dielectric layer or two or more second dielectric layers in the thickness direction on upper and lower surfaces of the capacitance formation portion Ac, respectively, and may fundamentally prevent damage to the internal electrodes 121 and 122 due to physical or chemical stress.

The first cover portion 112 and the second cover portion 113 do not include the internal electrodes 121 and 122 and may include the same dielectric material as the first dielectric layer 111 of the capacitance formation portion Ac. That is, the first cover portion 112 and the second cover portion 113 may include a dielectric material, for example, a barium titanate (BaTiO₃)-based dielectric material.

Meanwhile, a thickness tc of the cover portions 112 and 113 need not be specifically limited, and hereinafter, the description of the thickness tc of the cover portions 112 and 113 below may refer to the thickness tc of each of the first cover portion 112 and the second cover portion 113.

However, in order to easily achieve miniaturization and high capacity of the multilayer electronic component 100, an upper limit of the thickness tc of the cover portions 112 and 113 may be 100 μm or less or 50 μm or less, preferably 30 μm or less, and may be more preferably 20 μm or less for ultra-small products, and a lower limit thereof may be 5 μm or more, 10 μm or more, or 20 μm or more.

Here, the thickness tc of the cover portions 112 and 113 may refer to an average thickness of the cover portions 112 and 113.

Additionally, the average thickness tc of the cover portions 112 and 113 may refer to the average thickness tc of each of the first and second cover portions 112 and 113, or may refer to the average thickness tc of the first and second cover portions 112 and 113.

The average thickness tc of the cover portions 112 and 113 may be measured by scanning a cross-section of the body 110 in the length and thickness directions using a scanning electron microscope (SEM) at 10,000× magnification. More specifically, the average thickness tc may refer to an average value calculated by measuring the thickness at five points spaced apart from each other by equal intervals in the length direction in a scanned image of one cover portion 112 and 113.

Additionally, the average thickness tc of the cover portions 112 and 113 measured using the above-described method may have a value substantially equal to the average thickness of the cover portions 112 and 113 in the cross-section of the body 110 in the width and thickness directions.

Meanwhile, the multilayer electronic component 100 may include side margin portions 114 and 115, which are end regions of the internal electrodes 121 and 122 in the width direction.

More specifically, the side margin portions 114 and 115 may include a first side margin portion 114 disposed between the internal electrodes 121 and 122 and the fifth surface 5, and a second side margin portion 115 disposed between the internal electrodes 121 and 122 and the sixth surface 6.

As illustrated, the side margin portions 114 and 115 may refer to a region between both ends of the first and second internal electrodes 121 and 122 in the width direction and a boundary surface of the body 110, based on the cross-section of the body 110 in the width and thickness directions.

The side margin portions 114 and 115 may refer to a region of the ceramic green sheet excluding the internal electrodes 121 and 122, when an internal electrode paste is applied to the ceramic green sheet applied to the capacitance formation portion Ac except for a region in which the side margin portions 114 and 115 are to be formed.

However, the present disclosure is not particularly limited, and the side margin portions 114 and 115 may be formed by applying a conductive paste to the ceramic green sheet applied to the capacitance formation portion Ac, except for a region in which the side margin portions 114 and 115 are to be formed, and forming internal electrodes 121 and 122, and, to suppress a step difference caused by the internal electrodes 121 and 122, cutting the body 110 so that the stacked internal electrodes 121 and 122 are exposed to the fifth and sixth surfaces 5 and 6 of the body 110, and then, disposing and stacking a single third dielectric layer or two or more third dielectric layers on both end surfaces of the capacitance formation portion Ac in the width direction.

The side margin portions 114 and 115 may fundamentally prevent damage to the internal electrodes 121 and 122 due to physical or chemical stress.

The first side margin portion 114 and the second side margin portion 115 do not include internal electrodes 121 and 122 and may include the same material as the first dielectric layer 111, and may correspond to, for example, a portion of the first dielectric layer 111. That is, the first side margin portion 114 and the second side margin portion 115 may include a dielectric material, for example, a barium titanate (BaTiO₃)-based dielectric material.

Meanwhile, a width wm of the side margin portions 114 and 115 need not be specifically limited, and hereinafter, the description of the width wm of the side margin portions 114 and 115 may refer to a width wm of each of the first side margin portion 114 and the second side margin portion 115.

To more easily achieve miniaturization and high capacity of the multilayer electronic component 100, an upper limit of the width wm of the side margin portions 114 and 115 may be 50 μm or less, preferably 30 μm or less, and more preferably 20 μm or less for ultra-small products, and a lower limit thereof may be 5 μm or more, 10 μm or more, or 20 μm or more.

Here, the width wm of the side margin portions 114 and 115 may refer to an average width wm of the side margin portions 114 and 115.

In addition, the average width wm of the side margin portions 114 and 115 may refer to an average width wm of each of the first and second side margin portions 114 and 115, or may refer to the average width wm of the first and second side margin portions 114 and 115.

The average width wm of the side margin portions 114 and 115 may be measured by scanning an image of a cross-section of the body 110 in the width and thickness directions using a scanning electron microscope (SEM) at 10,000× magnification. More specifically, the average width wm may refer to an average value calculated by measuring a width at five points spaced apart from each other by equal intervals in the thickness direction from a scanned image of one side margin portion 114 and 115.

In an example embodiment of the present disclosure, a multilayer electronic component 100 is described as having a structure with two external electrodes 131 and 132. However, the number and shape of the external electrodes 131 and 132 may vary depending on the shape of the internal electrodes 121 and 122 or other purposes.

The external electrodes 131 and 132 may be disposed on the body 110 and connected to the internal electrodes 121 and 122.

More specifically, the external electrodes 131 and 132 may include first and second external electrodes 131 and 132 disposed on the third and fourth surfaces 3 and 4 of the body 110, respectively, and connected to the first and second internal electrodes 121 and 122, respectively. That is, the first external electrode 131 may be disposed on the third surface 3 of the body and connected to the first internal electrode 121, and the second external electrode 132 may be disposed on the fourth surface 4 of the body and connected to the second internal electrode 122.

Furthermore, the external electrodes 131 and 132 may extend to portions of the first and second surfaces 1 and 2 of the body 110, or may extend to portions of the fifth and sixth surfaces 5 and 6 of the body 110. That is, the first external electrode 131 may be disposed on the third surface 3 of the body 110 and portions of the first, second, fifth, and sixth surfaces 1, 2, 5 and 6 of the body 110, and the second external electrode 132 may be disposed on the fourth surface 4 of the body 110 and portions of the first, second, fifth, and sixth surfaces 1, 2, 5 and 6 of the body 110.

The external electrodes 131 and 132 may include connection portions disposed on the third and fourth surfaces 3 and 4 of the body 110, and band portions extending from the connection portions onto portions of the first and second surfaces 1 and 2 of the body 110. Here, the connection portion and the band portion may refer to the corresponding regions.

More specifically, the first external electrode 131 may include a first connection portion disposed on the third surface 3 of the body 110, and a first band portion extending from the first connection portion to portions of the first and second surfaces 1 and 2, and the second external electrode 132 may include a second connection portion disposed on the fourth surface 4 of the body 110, and a second band portion extending from the second connection portion to portions of the first and second surfaces 1 and 2.

The first band portion may include a first-first band portion extending from the first connection portion to a portion of the first surface 1, and a first-second band portion extending from the first connection portion to a portion of the second surface 2, and the second band portion may include a second-first band portion extending from the second connection portion to a portion of the first surface 1, and a second-second band portion extending from the second connection portion to a portion of the second surface 2.

In the present disclosure, unless otherwise specifically contradictory, the description of the band portion may correspond to the description of the first band portion and the second band portion, respectively, and further, may correspond to the description of the first-first band portion, the first-second band portion, the second-first band portion, and the second-second band portion.

The external electrodes 131 and 132 may be formed using any material that is electrically conductive, such as metal, and a specific material thereof may be determined based on electrical characteristics, structural stability, and the like, and the external electrodes 131 and 132 may further have a multilayer structure.

For example, the external electrodes 131 and 132 may include a first electrode layer disposed on the body 110 and a second electrode layer disposed on the first electrode layer.

Here, the first and second electrode layers may preferably be layers that are distinct from each other. However, the present disclosure is not particularly limited, and the first and second electrode layers may be layers classified according to a manufacturing process order, and the first and second electrode layers may not be distinct from each other and may be observed as a single layer.

In the present disclosure, “distinct” may mean that two layers are distinguished due to physical differences, chemical differences, and/or simple optical differences, and the present disclosure is not particularly limited thereto, and the distinction between layers may be determined by the presence or absence of an “interface.” The interface may refer to a surface in a state in which two layers in contact with each other are distinguishable from each other, and for example, the interface may refer to a state in which the distinction is possible based on differences in components, such as those observed through EDS analysis using equipment such as a scanning electron microscope (SEM).

The first electrode layer may be formed by transferring a sheet including a conductive metal onto the body 110, or by applying a conductive paste for external electrodes including a conductive metal to the body 110 and then sintering the conductive paste, or may be formed by dipping the body 110 in the conductive paste for external electrodes including a conductive metal, but the present disclosure is not particularly limited thereto.

A more specific example of the first electrode layer may be a sintered electrode including a conductive metal and glass.

The conductive metal included in the first electrode layer may be a material having excellent electrical conductivity, and for example, the conductive metal may include one or more selected from the group consisting of nickel (Ni), copper (Cu), palladium (Pd), silver (Ag), gold (Au), platinum (Pt), tin (Sn), tungsten (W), titanium (Ti), and alloys thereof, but is not particularly limited thereto.

Furthermore, the glass included in the first electrode layer may serve to enhance bonding with the body 110.

The second electrode layer may serve to improve mounting characteristics and may be a plating layer formed on the first electrode layer, but is not particularly limited thereto.

The type of the second electrode layer is not particularly limited, and may include, for example, at least one of nickel (Ni), tin (Sn), silver (Ag), palladium (Pd), and alloys thereof.

The second electrode layer may be a single layer or a plurality of layers.

More specifically, for example, the second electrode layer may be a nickel (Ni) electrode layer or a tin (Sn) electrode layer, and may be formed by sequentially forming a nickel (Ni) electrode layer and a tin (Sn) electrode layer on the first electrode layer. Alternatively, the second electrode layer may be formed by sequentially forming a tin (Sn) electrode layer, a nickel (Ni) electrode layer, and a tin (Sn) electrode layer. Furthermore, the second electrode layer may include a plurality of nickel (Ni) electrode layers and/or a plurality of tin (Sn) electrode layers.

The coating layer 151 may be disposed on at least a portion of at least one of the body 110 and the external electrodes 131 and 132.

That is, the coating layer 151 may be disposed on at least a portion of the body 110, or on at least a portion of the external electrodes 131 and 132, and may be disposed on at least a portion of each of the body 110 and the external electrodes 131 and 132.

More specifically, for example, the coating layer 151 may be disposed on at least a portion of the first surface 1 and the second surface 2, and more preferably, on at least a portion of the first surface 1, the second surface 2, the fifth surface 5, and the sixth surface 6.

Additionally, the coating layer 151 may be disposed on at least a portion of at least one of the first external electrode 131 and the second external electrode 132, and preferably, on at least a portion of both the first external electrode 131 and the second external electrode 132.

Specifically, the coating layer 151 may be disposed on at least a portion of at least one of the connection portion or the band portion of the external electrode, and more specifically, on at least a portion of the first and second connection portions and the first and second band portions, and preferably, on the first and second connection portions and the first-second and second-second band portions.

In this case, when an average thickness of the coating layer 151a disposed on the first surface 1 among the coating layers 151 is referred to as TCL1, and an average thickness of the remaining coating layers 151b excluding the coating layer 151a disposed on the first surface 1 is referred to as TCL2, TCL2<TCL1 and 2 μm≤TCL2≤6 μm may be satisfied.

Here, an average thickness TCL1 of the coating layer 151a disposed on the first surface 1 may refer to an average thickness of the coating layer 151 in a region of the first surface 1 in which the external electrodes 131 and 132 are not formed. An average thickness TCL2 of the remaining coating layers 151b, excluding the coating layer 151a disposed on the first surface 1, may refer to an average thickness of the coating layer 151 disposed on the second surface 2, or may refer to an average thickness of the coating layer disposed on at least a portion of at least one of the connection portion or the band portion of the external electrode, and the average thickness may refer to, preferably, an average thickness of the coating layer 151 disposed on the second surface 2 and the connection portion of the external electrode, but the present disclosure is not particularly limited thereto.

A method of measuring the average thickness of the coating layer 151 may be as follows, but the present disclosure is not particularly limited thereto. First, a cross-section of the multilayer electronic component 100 in the longitudinal and thickness directions may be observed using a scanning electron microscope (SEM), or the like, and then, the thicknesses at 10 points among the coating layers 151 disposed in each region may be measured to obtain the average thickness. For example, the average thickness of the coating layer 151a disposed on the first surface 1 may be obtained by measuring the thickness of the coating layer 151a on the first surface 1 on which the external electrodes 131 and 132 are not formed, at 10 points spaced apart from each other in the longitudinal direction, and averaging the measurements. Furthermore, the thickness of the remaining coating layers 151b, excluding the coating layer 151a disposed on the first surface 1, more specifically, a thickness of the coating layer 151b disposed on the second surface 2, may be measured at 10 points spaced apart from each other in the longitudinal direction, and also, the thickness (referring to a longitudinal length in FIG. 2) of the coating layer 151b disposed on the connection portion of the external electrode may be measured at 5 points spaced apart from each other in the thickness direction, so that the measured thicknesses thereof are averaged to obtain an average value thereof.

When the average thickness TCL1 of the coating layer 151a disposed on the first surface 1 and the average thickness TCL2 of the remaining coating layers 151b excluding the coating layer 151a disposed on the first surface 1 satisfy the relation TCL2<TCL1, acoustic noise may be more effectively improved, and miniaturization of the multilayer electronic component 100 may be achieved, thereby improving the mounting density when mounted on a substrate.

More specifically, when the average thickness TCL1 of the coating layer 151a disposed on the first surface 1 among the coating layers 151 is the thickest, for example, when the relation TCL2<TCL1 is satisfied, vibrations caused by deformation in a mounting surface area of the multilayer electronic component 100 may be effectively prevented from being transmitted to the substrate, and thus acoustic noise may be more effectively reduced.

When the average thickness of the coating layer 151 for each region is TCL1≤TCL2, the acoustic noise reduction effect may be minimal.

Furthermore, when the average thickness TCL2 of the remaining coating layers 151b, excluding the coating layer 151a disposed on the first surface 1, is 2 μm≤TCL2≤6 μm, acoustic noise may be more effectively reduced, and miniaturization of the multilayer electronic component 100 may be achieved, thereby improving the mounting density when mounted on a substrate.

When TCL2 is less than 2 μm (TCL2<2 μm), the acoustic noise reduction effect may be minimal, and when TCL2 exceeds 6 μm (6 μm<TCL2), the acoustic noise reduction effect may be minimal or it may be difficult to achieve miniaturization of the multilayer electronic component 100.

In this case, the coating layer 151 may have a Young's modulus of 20 MPa or more and 1 GPa or less.

As the Young's modulus of the coating layer 151 of 20 MPa or more and 1 GPa or less is satisfied, acoustic noise may be more effectively improved, and miniaturization of the multilayer electronic component 100 may be achieved, thereby improving the mounting density when mounted on a substrate.

Even when the Young's modulus of the coating layer 151 is less than 20 MPa or greater than 1 GPa, the acoustic noise reduction effect may be minimal.

The Young's modulus of the coating layer 151 may be determined using nanoindentation, mechanical testing, stress-strain curves, ultrasonic velocity measurement, and Atomic Force Microscopy (AFM), but the present disclosure is not limited thereto. Other methods and/or tools appreciated by one of ordinary skill in the art, even if not described in the present disclosure, may also be used.

More specifically, nanoindentation is a method of using a microscopic indenter to indent a material to a precise depth, and measuring a relationship between the force and depth generated during this process to determine Young's modulus. Mechanical testing is an indirect method to estimate Young's modulus through microhardness testing, and is a method of micro-indenting a material using a hard indenter (e.g., Vickers or Knoop hardness tester) and then estimating the indentation depth or Young's modulus. Stress-strain curves are a method of applying constant force to a material, measuring a resulting deformation, and then plotting a stress-strain curve to determine Young's modulus. Ultrasonic velocity measurement is a method of measuring the ultrasonic velocity of a material, through which Young's modulus is estimated, and Young's modulus may be estimated using a relationship between the material's strength or density and velocity. Atomic force microscopy (AFM) is a high-resolution analytical method that may analyzes the mechanical properties of materials by measuring interatomic interactions, and Young's modulus measurement using AFM may measure deformation in an ultrafine domain, and based thereon, Young's modulus may be calculated.

The coating layer 151 may have insulating properties and serve to prevent external moisture penetration or absorb external impacts.

A material of the coating layer 151 is not particularly limited, but may include at least one of an organic compound including at least one of an epoxy resin and a urethane resin; or an inorganic oxide including at least one of silicon (Si), titanium (Ti), and aluminum (Al), and the coating layer may include, preferably, an epoxy resin.

There is no particular limitation on the method for forming the coating layer 151.

For example, after forming the external electrodes 131 and 132 on the body 110, the coating layer 151 may be printed, or manufactured as a sheet and transferred, or may be dipped into a paste including a raw material for the coating layer 151, thereby forming the coating layer 151.

Furthermore, after mounting the multilayer electronic component 100 on a substrate 210, the coating layer 151 may be formed using the methods described above.

The size of the multilayer electronic component 100 is not particularly limited.

However, in order to simultaneously achieve miniaturization and high capacity, since the thickness of the dielectric layer and internal electrodes should be reduced to increase the number of stacked layers, the effects of the present disclosure may be more remarkable in a multilayer electronic component 100 having a size of 2012 mm (length×width: 2.0 mm×1.2 mm, with a length and width tolerance of +10%) or less.

Furthermore, the multilayer electronic component 100 may have a width greater than a length.

### Board Having Multilayer Electronic Component Mounted Thereon

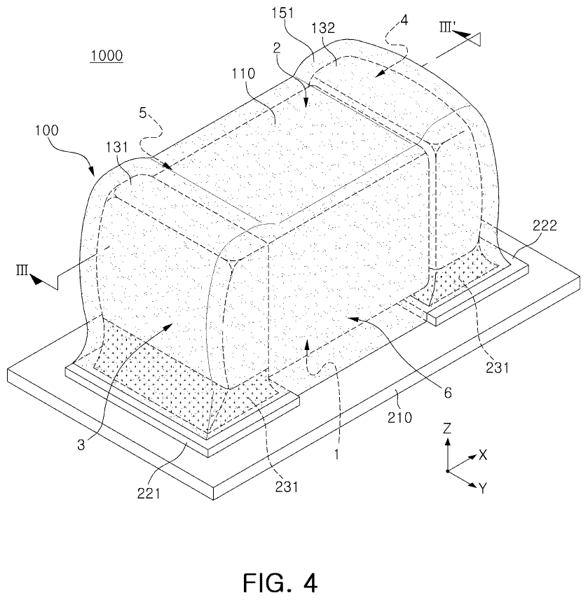

FIG. 4 schematically illustrates a perspective view of a board having a multilayer electronic component mounted thereon according to another example embodiment of the present disclosure.

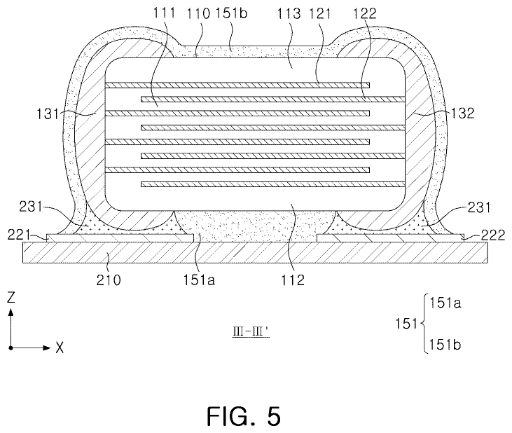

FIG. 5 schematically illustrates a cross-sectional view taken along line III-III′ of FIG. 4.

Hereinafter, a multilayer electronic component mounted thereon according to an example embodiment of the present disclosure will be described in detail with reference to FIGS. 4 and 5.

In an example embodiment, portions of the multilayer electronic component 100, identical to those described above, will be omitted.

According to another example embodiment of the present disclosure, a board 1000 having a multilayer electronic component mounted thereon may include: a substrate 210; electrode pads 221 and 222 disposed on the substrate; a multilayer electronic component 100 including a body 110 including a dielectric layer 111 and internal electrodes 121 and 122 disposed alternately with the dielectric layer 111 in a thickness direction, and including first and second surfaces 1 and 2 opposing each other in the thickness direction, third and fourth surfaces 3 and 4 connected to the first and second surfaces 1 and 2 and opposing each other in the length direction, and fifth and sixth surfaces 5 and 6 connected to the first to fourth surfaces 1, 2, 3 and 4 and opposing each other in a width direction, external electrodes 131 and 132 disposed on the body 110, and a coating layer 151 disposed on the first and second surfaces 1 and 2; and a solder 231 connecting the external electrodes 131 and 132 and the electrode pads 221 and 222, and when an average thickness of the coating layer 151a disposed on the first surface 1, among the coating layers 151, is referred to as TCL1, and an average thickness of the remaining coating layers 151b excluding the coating layer 151a disposed on the first surface 1 is referred to as TCL2, the conditions TCL2<TCL1 and 2 μm≤TCL2≤6 μm may be satisfied.

In this example embodiment, the details regarding the coating layer 151 are the same as those described above and are therefore omitted.

The multilayer electronic component 100 may be mounted on the substrate 210, that is, the coating layer 151 of the multilayer electronic component in the board 1000 may be disposed so as to be in contact with the substrate 210.

Additionally, the coating layer 151 may be disposed in a region between the body 110 and the substrate 210 by 90% or more, 95% or more, 97% or more, preferably 99% or more.

Here, the coating layer 151 being disposed in the region between the body 110 and the substrate 210 by 90% or more may mean that the coating layer 151 is filled in the mounting surface of the body 110, for example, when observing a cross-section in the length and thickness directions (e.g., L-T direction) at a center in the width direction in a state in which the multilayer electronic component 100 including the coating layer 151 and the substrate 210 are included, an average thickness of the coating layer 151 disposed on the first surface 1 (where the external electrodes 131 and 132 are not disposed) is 90% or more relative to an average thickness between the first surface 1 and the substrate 210 in the thickness direction. For example, at least a portion of the region between the first surface 1 and the substrate 210, specifically, a majority of the region (e.g., 90% or more), may be filled with the coating layer 151.

In addition, it may be preferable that the coating layer 151 is disposed in the region between the first surface 1 and the substrate 210 in an amount of 99% or more (up to 100%). This may imply that the coating layer 151 is substantially completely filled therein, thereby providing a structure in which the coating layer 151 connects the body 110 and the substrate 210 is preferred.

Preferably, when the coating layer 151a disposed on the first surface 1 is disposed so as to be in contact with the substrate 210, vibration due to deformation occurring near the mounting surface of the multilayer electronic component 100, for example, the first surface 1, may be effectively prevented from being transmitted to the substrate 210, and thus, acoustic noise may be more effectively reduced.

The present disclosure will be described in more detail below through test examples. However, these examples are intended to facilitate a more specific understanding of the disclosure and are not intended to limit the scope of the present disclosure.

### Test Examples

The following [Table 1] shows results obtained by measuring the acoustic noise values according to the average thickness and Young's modulus of the coating layer (including epoxy resin) when the coating layer was formed after a multilayer electronic component was mounted on a substrate.

The average thickness of the coating layer is an average value obtained by measuring and averaging the thickness of the coating layer disposed on the second surface of the body, the first and second connection portions, and the first-second and second-second band portions.

Acoustic noise was measured and recorded when voltage/current was applied after mounting the multilayer electronic component on the substrate, and when the noise exceeded 60 dBA, the acoustic noise reduction effect was evaluated as minimal, and when the noise was 60 dBA or less, the acoustic noise reduction effect was evaluated as excellent.

Test Example 1 did not form a coating layer, while Test Examples 2 to 13 formed the coating layer with different average thicknesses and Young's moduli. In Test Examples 2 to 13, the coating layer was formed to completely fill the region between a mounting surface (e.g., the first surface) of the body and the substrate as much as possible, and was formed to fill at least 90% of the region.

TABLE 1

| | Average Thickness | Young's modulus | |
|---|---|---|---|
| | of Coating | of Coating | Acoustic |
| | Thickness (μm) | layer (MPa) | Noise (dBA) |
| Test Example 1 | 0 | — | 65 |
| Test Example 2 | 2 | 20 | 44.5 |
| Test Example 3 | 2 | 250 | 49.1 |
| Test Example 4 | 2 | 1000 | 55.1 |
| Test Example 5 | 2 | 3000 | 62.1 |
| Test Example 6 | 6 | 20 | 43.5 |
| Test Example 7 | 6 | 250 | 50.1 |
| Test Example 8 | 6 | 1000 | 56.7 |
| Test Example 9 | 6 | 3000 | 61.1 |
| Test Example 10 | 10 | 20 | 48.0 |
| Test Example 11 | 10 | 250 | 58.2 |
| Test Example 12 | 10 | 1000 | 61.2 |
| Test Example 13 | 10 | 3000 | 63.3 |

Test Example 1 is a case in which a coating layer was not formed, which had the highest acoustic noise at 65 dBA.

Test Examples 2 to 5 were manufactured to have Young's modulus of 20 MPa, 250 MPa, 1 GPa (=1000 MPa), and 3 GPa (=3000 MPa), respectively, when the average thickness of the coating layer was 2 μm. While the acoustic noise of Test Examples 2 to 4 was reduced to 44.5 dBA, 49.1 dBA, and 55.1 dBA, respectively, the acoustic noise of Test Example 5 was reduced to 62.1 dBA, which shows minimal reduction.

Test Examples 6 to 9 were manufactured to have Young's moduli of 20 MPa, 250 MPa, 1 GPa (=1000 MPa), and 3 GPa (=3000 MPa), respectively, when the average coating thickness was 6 μm. The acoustic noise levels of Test Examples 6 to 8 were reduced to 43.5 dBA, 50.1 dBA, and 56.7 dBA, respectively, while the acoustic noise level of Test Example 9 was reduced to 61.1 dBA, which shows minimal reduction.

Test Examples 10 to 13 were manufactured to have Young's moduli of 20 MPa, 250 MPa, 1 GPa (=1000 MPa), and 3 GPa (=3000 MPa), respectively, when the average coating thickness was 10 μm. The acoustic noise levels of Test Examples 10 and 11 were reduced to 48.0 dBA and 58.2 dBA, respectively, while the acoustic noise levels of Test Examples 12 and 13 were reduced to 61.2 dBA and 63.3 dBA, respectively, which shows minimal reduction.

Based thereon, it may be confirmed that when the average thickness of the coating layer is 2 μm or more and 6 μm or less, and the Young's modulus is 20 MPa or more and 1 GPa or less, the acoustic noise reduction effect is further improved.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

Furthermore, the expression ‘example embodiment’ used in the present disclosure does not mean the same ‘embodiment’, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A multilayer electronic component, comprising:
a body including a dielectric layer and internal electrodes alternately disposed with the dielectric layer in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction;
an external electrode disposed on the body; and
a coating layer disposed on the first and second surfaces, the coating layer including a first portion disposed on the first surface, and a second portion that is free of the first portion,
wherein, when an average thickness of the first portion is referred to as TCL1 and an average thickness of the second portion is referred to as TCL2, TCL2<TCL1 and 2 μm≤TCL2≤6 μm are satisfied.

2. The multilayer electronic component according to claim 1, wherein the coating layer has a Young's modulus of 20 MPa or more and 1 GPa or less.

3. The multilayer electronic component according to claim 1, wherein the external electrode includes:
a first external electrode including a first connection portion disposed on the third surface, and first-first and first-second band portions extending from the first connection portion to portions of the first and second surfaces, respectively; and
a second external electrode including a second connection portion disposed on the fourth surface, and second-first and second-second band portions extending from the second connection portion to portions of the first and second surfaces, respectively, and
the coating layer is disposed on the first and second connection portions and the first-second and second-second band portions.

4. The multilayer electronic component according to claim 1, wherein the coating layer includes at least one selected from the group consisting of an organic compound and an inorganic oxide, the organic compound includes at least one selected from the group consisting of an epoxy resin and a urethane resin, and the inorganic oxide includes at least one selected from the group consisting of silicon (Si), titanium (Ti), and aluminum (Al).

5. The multilayer electronic component according to claim 1, wherein the coating layer has a Young's modulus of 20 MPa or more and 1 GPa or less,
the external electrode includes:
a first external electrode including a first connection portion disposed on the third surface, and first-first and first-second band portions extending from the first connection portion to portions of the first and second surfaces, respectively; and
a second external electrode including a second connection portion disposed on the fourth surface, and second-first and second-second band portions extending from the second connection portion to portions of the first and second surfaces, respectively, and
the coating layer is disposed on the first and second connection portions and the first-second and second-second band portions.

6. The multilayer electronic component according to claim 5, wherein the coating layer includes epoxy resin.

7. The multilayer electronic component according to claim 5, wherein the coating layer includes urethane resin.

8. The multilayer electronic component according to claim 5, wherein the coating layer includes an inorganic oxide that includes silicon (Si).

9. The multilayer electronic component according to claim 5, wherein the coating layer includes an inorganic oxide that includes titanium (Ti).

10. The multilayer electronic component according to claim 5, wherein the coating layer includes an inorganic oxide that includes aluminum (Al).

11. A board having a multilayer electronic component mounted thereon, comprising:
a substrate;
an electrode pad disposed on the substrate;
a multilayer electronic component including a body having a dielectric layer and internal electrodes alternately disposed with the dielectric layer in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction, an external electrode disposed on the body, and a coating layer disposed on the first and second surfaces, the coating layer including a first portion disposed on the first surface, and a second portion that is free of the first portion; and
a solder connecting the external electrode and the electrode pads,
wherein, when an average thickness of the first portion is referred to as TCL1 and an average thickness of the second portion is referred to as TCL2, TCL2<TCL1 and 2 μm≤TCL2≤6 μm are satisfied.

12. The board having a multilayer electronic component mounted thereon according to claim 11, wherein the coating layer has a Young's modulus of 20 MPa or more and 1 GPa or less.

13. The board having a multilayer electronic component mounted thereon according to claim 11, wherein the external electrode includes:
a first external electrode including a first connection portion disposed on the third surface, and first-first and first-second band portions extending from the first connection portion to portions of the first and second surfaces, respectively; and
a second external electrode including a second connection portion disposed on the fourth surface, and second-first and second-second band portions extending from the second connection portion to portions of the first and second surfaces, respectively, and
the coating layer is disposed on the first and second connection portions and the first-second and second-second band portions.

14. The board having a multilayer electronic component mounted thereon according to claim 11, wherein the coating layer is disposed on the solder.

15. The board having a multilayer electronic component mounted thereon according to claim 11, wherein the coating layer is disposed so as to be in contact with the board.

16. The board having a multilayer electronic component mounted thereon according to claim 11, wherein the coating layer is disposed in a region between the body and the board by 90% or more.

17. The board having a multilayer electronic component mounted thereon according to claim 11, wherein the coating layer includes at least one selected from the group consisting of an organic compound and an inorganic oxide, the organic compound includes at least one selected from the group consisting of an epoxy resin and a urethane resin, and the inorganic oxide includes at least one selected from the group consisting of silicon (Si), titanium (Ti), and aluminum (Al).
